(19) United States
(12) Patent Application Publication
(10) Pub. No.: US 2008/0185679 A1
(43) Pub. Date: Aug. 7, 2008

(54) INDUCTOR LAYOUT AND MANUFACTURING METHOD THEREOF

(75) Inventors: Tsun-Lai Hsu, Hsinchu Hsien (TW); Hsiao-Chin Chen, Hsinchu City (TW); Shey-Shi Lu, Taipei City (TW); Jen-Chung Chang, Taoyuan County (TW); Chia-Jung Hsu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignees: UNITED MICROELECTRONICS CORP., Hsinchu (TW); NATIONAL TAIWAN UNIVERSITY, Taipei (TW)

(21) Appl. No.: 11/550,809

(22) Filed: Oct. 19, 2006

(51) Int. Cl. H01L 29/00; H01L 21/02

(52) U.S. Cl. 257/531; 438/381; 257/E29.001; 257/E21.022

(57) ABSTRACT

An inductor layout and manufacturing method thereof are provided. The inductor layout includes a substrate and a conductive path. The substrate includes at least an active region, wherein the active region includes at least a circuit. The conductive path is disposed over the substrate and arranged near the edge of the active region along the direction of the edge of the active region. Wherein, two ends of the conductive path are the two ends of the inductor.

### BACKGROUND OF THE INVENTION

1. Field of the Invention

The present invention relates to an inductor. More particularly, the present invention relates to an inductor layout and manufacturing method thereof.

2. Description of Related Art

Inductor is an essential passive device, which is widely used in radio frequency (RF) circuits, voltage controlled oscillators (VCO), low noise amplifiers (LNA) or other power amplifiers (PA). For example, combining the inductor in a single chip is the best solution in wireless communication system. Owing to the improvement to semiconductor technology, the inductor integrated in the chip can have proper quality factor Q (for example, 8˜10) in the application of GHz band by using Complementary Metal-Oxide Semiconductor (CMOS) process. However, the conventional inductor layout occupies a large amount of the chip area (about 0.3 mm×0.3 mm), thus it is disadvantageous for the application of high density integration.

FIG. 1 is a circuit diagram of the VCO (voltage control oscillator). The VCO 100 includes a resistor 141, P-type transistors 131 and 132, diodes 121 and 122, capacitors 111, 112, 113 and 114, and inductors 101 and 102. According the bias voltage of the pad BV, the VCO 100 decides the oscillating frequency of the output signal output by the pad OUT+ and OUT−. FIG. 2 illustrates the layout of implementing the conventional VCO 100 of FIG. 1. Referring to FIG. 1 and FIG. 2, only the layout is emphasized, and the connection of the devices is omitted here. It can be seen from FIG. 2 that the layout area of inductors 101 and 102 is larger than the total area of resistor 141, P-type transistors 131 and 132, diodes 121 and 122, capacitors 111˜114. Because the inductors 101 and 102 occupy a large portion of the chip area, the cost of the integrated circuit is increased.

It is required for a high density circuit design to use the smallest chip area to lower manufacturing cost. To minimize the chip area and simultaneously increase the inductor Q value, the conventional technology (for example, U.S. Pat. No. 6,455,885 & U.S. Pat. No. 6,459,135) forms an inductor having a thick dielectric layer (usually polyimide) in the post-IC processing technology. However, the formation of the inductor requires a special post-IC process, which increases the cost and production complexity.

In addition, U.S. Pat. No. 6,518,165 discloses another inductor layout. The prior art disposes the inductor over the circuit area to save the chip area. In the conventional technology, the wire of the inductor is overlapped above the circuit area, which is unavoidable that a coupling effect between the signal of the inductor and the signal in the circuit area will incur. To reduce the coupling effect, U.S. Pat. No. 6,518,165 adopts a special processing method, which completely removes the dielectric materials under the inductor and raises the inductor as high as possible to be far away from the circuit area. Nevertheless, those skilled in the art should know that, though this method can save chip area, a special process is required for forming the inductor. Thus, the conventional technology is not practical to the application of this field as it increases cost and production complexity.

### SUMMARY OF THE INVENTION

One objective of the present invention is to provide an inductor layout, which can be applied to any standard process and saves the chip area.

Another objective of the present invention is to provide a method for manufacturing an inductor, which, without increasing cost and production complexity, saves the area the inductor occupies in the chip area.

Based on the above and other objectives, the present invention provides an inductor layout, which includes a substrate and a conductive path. The substrate includes at least an active region, wherein the active region includes at least a circuit. The conductive path is disposed near the edge of the active region over the substrate and arranged along the direction of the edge of the active region. Wherein, two ends of the conductive path are the two ends of the inductor.

From another aspect, the present invention provides a method for manufacturing the inductor, which includes the following steps. First, at least an active region is formed on the substrate, wherein the active region includes at least a circuit. Then, a conductive path is formed over the substrate. The conductive path is disposed near the edge of the active region and arranged along the direction of the edge of the active region. Two ends of the conductive path are the two ends of the inductor.

According to a preferred embodiment of the present invention, the conductive path circles the active region to form a single turn wire.

According to a preferred embodiment of the present invention, the conductive path circles the active region to form a multi-turn wire.

According to a preferred embodiment of the present invention, the conductive path is disposed in a conductive layer, and the conductive layer is above the substrate. The conductive layer can be the top metal layer.

According to a preferred embodiment of the present invention, the conductive path is disposed within several conductive layers, and the conductive layers are above the substrate.

According to a preferred embodiment, the method further includes forming a shielding layer, wherein the shielding layer is disposed between the inductor and the substrate.

In summary, according to the present invention, the conductive path of the inductor is disposed near the edge of the active region and extends toward the edge of the active region; therefore, under any inductor layout standard process, the area taken up by the inductor can be reduced without increasing the manufacturing cost and production complexity.

In order to make the aforementioned and other objectives, features and advantages of the present invention comprehensible, preferred embodiments accompanied with figures are described in detail below.

### BRIEF DESCRIPTION OF THE DRAWINGS

FIG. 1 is a circuit diagram of the VCO (voltage control oscillator).

FIG. 2 illustrates the layout of implementing the conventional VCO 100 of FIG. 1.

FIG. 3A is the perspective view of the inductor layout according to an embodiment of the present invention.

FIG. 3B is the top view of the inductor layout according to an embodiment of the present invention.

FIG. 4 is the characteristic drawing showing the control voltage v. output frequency of the VCO in FIG. 3A according the embodiment of the present invention.

FIG. 5 is the characteristic drawing showing the offset v. phase noise of the VCO in FIG. 3A according the embodiment of the present invention.

FIG. 6A illustrates the inductor layout according to another embodiment of the present invention.

FIG. 6B illustrates the inductor layout according to another embodiment of the present invention.

FIG. 6C illustrates the inductor layout according to another embodiment of the present invention.

FIG. 7A illustrates the inductor layout according to another embodiment of the present invention.

FIG. 7B illustrates the inductor layout according to another embodiment of the present invention.

### DESCRIPTION OF EMBODIMENTS

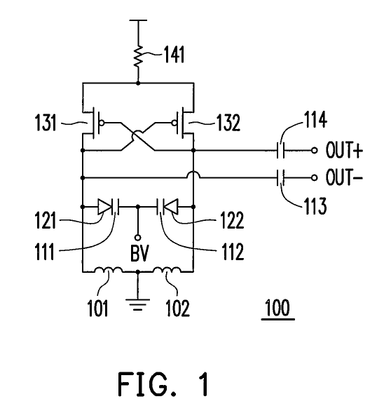

In the following, the VCO 100 of FIG. 1 is used as an example to illustrate the effect of the present invention when applying to the VCO 100. Those skilled in the art should know that the present invention can be applied to any ICs using the inductor according to the spirit of the present invention and the teachings or suggestion of the embodiments described below.

In the VCO 100 of FIG. 1, the coupled P-type transistors 131 and 132 are used for generating a negative feedback to maintain oscillation stability. The polysilicon resistor 141 is used to define tail current. Inductors 101, 102 and capacitors 11 1-1 14 decide the oscillation frequency of the VCO 100.

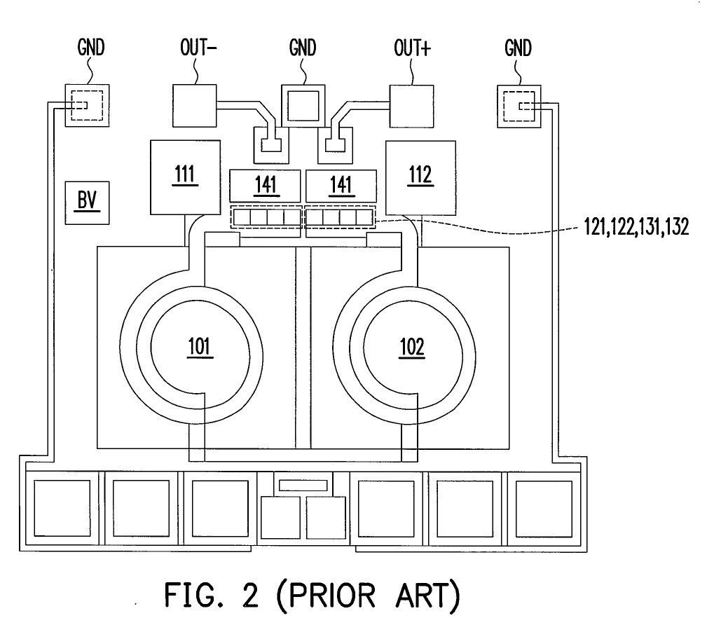

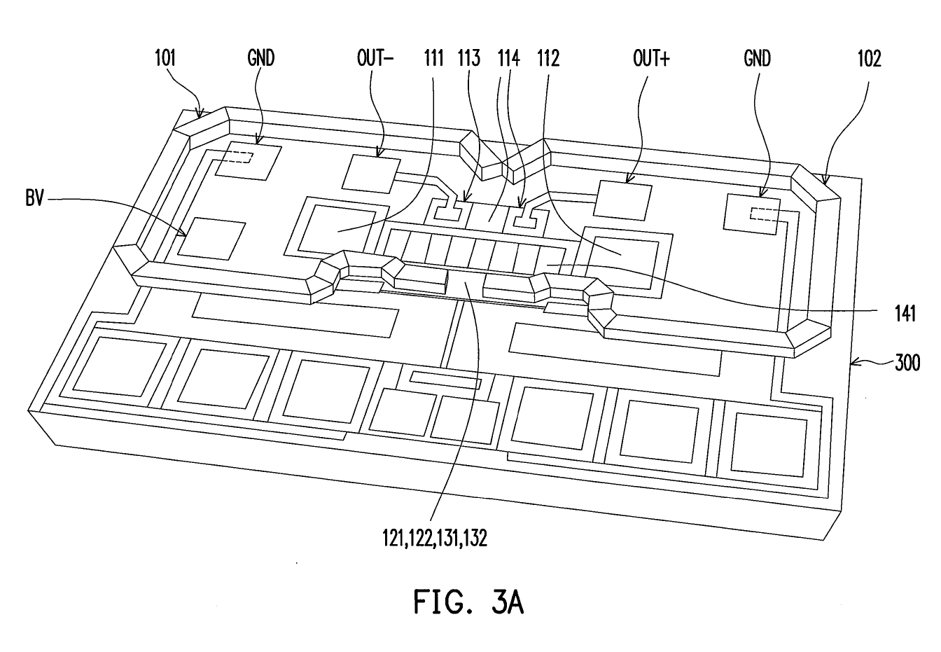

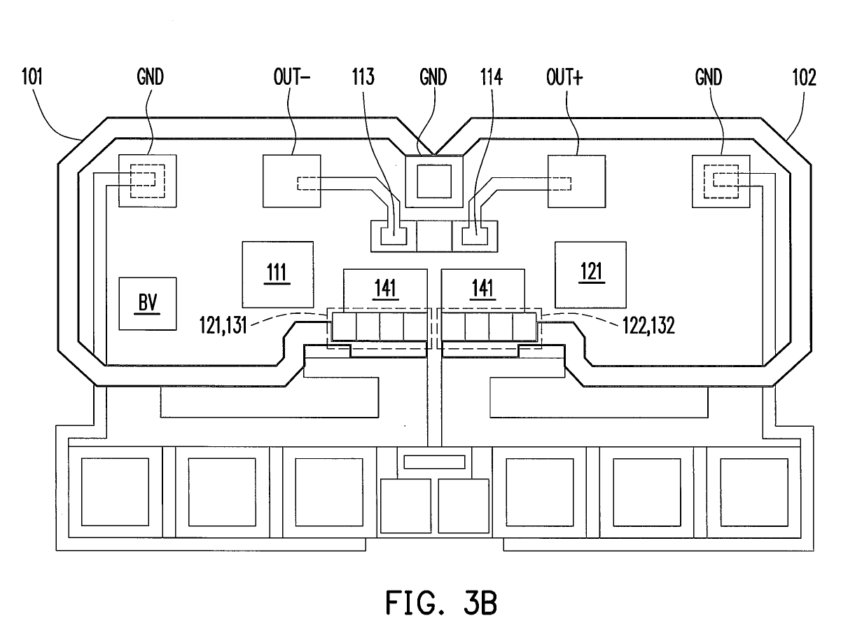

FIG. 3A is the perspective view of the inductor layout according to an embodiment of the present invention. FIG. 3B is the top view of the inductor layout according to an embodiment of the present invention. In order to compare with the conventional technology, the layout of the resistor 141, P-type transistors 131 and 132, diodes 121 and 122, capacitors 111 114 of the VCO 100 is the same as that shown in FIG. 2.

Please refer to FIG. 3A and FIG. 3B. The substrate 300 includes at least an active region, wherein the active region is a circuit consisted of resistor 141, P-type transistors 131 and 132, diodes 121 and 122, capacitors 111˜114, pad BV, OUT+ and OUT−. The conductive path of the inductor 101 is disposed near the left edge of the active region along the direction of the edge of the active region. The layout of the inductor 102 is similar to that of the inductor 101. The conductive path of the inductor 102 is disposed near the right edge of the active region along the direction of the edge of the active region.

FIG. 4 is the characteristic drawing showing the control voltage v. output frequency of the VCO in FIG. 3A according the embodiment of the present invention. This figure is a result of the VCO in FIG. 3A under an operation of 2.4V. Referring to FIG. 1, FIG. 3A and FIG. 4 together, the bias voltage of the pad BV is operated between 0V˜2.4V during the measurement process. It can be seen from FIG. 4 that the oscillation frequency of the pad OUT+ and OUT− of the VCO in FIG. 3A can be operated between 4519 MHz˜5019 MHz, which meets the frequency band 4824 MHz˜4960MHz the wireless local area networks WLAN (for example, 802.11b/g) requires.

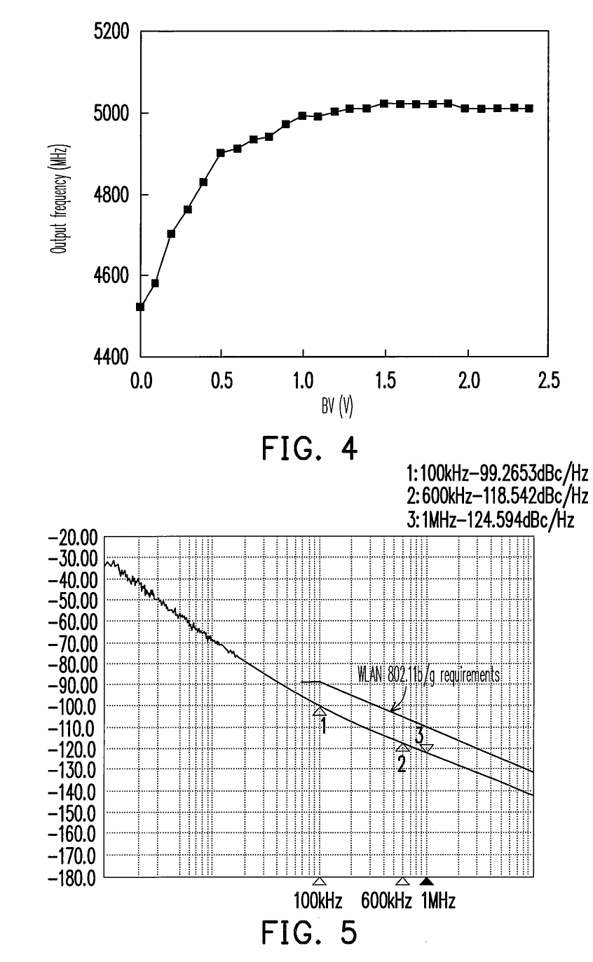

FIG. 5 is the characteristic drawing showing the offset v. phase noise of the VCO in FIG. 3A according the embodiment of the present invention. Referring to FIG. 1, FIG. 3A and FIG. 5, assuming the oscillation frequency of the pad OUT+ and OUT− is 4945.7 MHz, the inductor in FIG. 3A under 600 kHz and 1 MHz offset respectively obtains −118.5 dBc/Hz and −124.6 dBc/Hz phase noise. The result satisfies the phase noise specification (as shown in FIG. 5) the WLAN requires (for example, 802.11b/g).

The comparison of the present embodiment with the prior art is shown in Table 1. To objectively compare the advantages and disadvantages of the present embodiment with the prior art, the figure-of-merit (hereinafter “FOM”) is used as a combinational evaluation indicator of the frequency and power consumption. The calculation of FOM is as follows:

$$FOM = 10 log [ {P}_{sup} \cdot {( \frac{{f}_{off}}{{f}_{0}} )}^{2} ] + L \{ {f}_{off} \}$$

Wherein, L{f_{off}} represents the SSB phase noise measurement when the output frequency is fₒ and the offset frequency is f_{off}; Pₛᵤₚ represents the power consumption (unit: mW) of the VCO.

Table 1: a characteristic comparison on the VCO when respectively applying the inductor layout of the present embodiment and applying the conventional technology.

| | Oscillation | | Tuning | | |
|---|---|---|---|---|---|
| | frequency | Phase noise | range | FOM | Chip area |
| | (MHz) | (dBc/Hz) | (%) | (dBc/Hz) | (mm²) |
| Present | 4.9 | −124.6 | 10.5 | −184.7 | 0.224 |
| embodiment | | | | | |
| Reference 1 | 5.6 | −116.7 | 11.3 | −184.0 | 0.392 |
| Reference 2 | 5.3 | −126.0 | 3.8 | −188.2 | 0.705 |
| Reference 3 | 4.0 | −117.0 | 13.0 | −180.3 | 0.500 |

In Table 1, Reference 1 is “A 5 GHz transformer-coupled CMOS VCO using bias-level shifting technique” published in “RFIC Symposium”, pp. 127-130, 2004; Reference 2 is “High performance SOI and bulk CMOS 5 GHz VCOs” published in RFIC Symposium, pp. 93-96, 2002; and Reference 3 is “Influence of novel MOS varactors on the performance of a fully integrated UMTS VCO in standard 0.25-um CMOS technology”, Solid-State Circitits, vol. 37, No. 7, PP. 953-958, July 2002. It can be seen from Table 1 that the efficiency of the VCO applying the inductor layout of the present embodiment is similar to (or even better) that of the conventional technology, but the chip area of the present embodiment is the smallest.

Referring to FIG. 3A and FIG. 3B, a designer can choose to dispose the sensitive devices near the edge of the active region, so as to alleviate the coupling effect. For example, in the present embodiment, the active devices such as transistors 131 and 132, and diodes 121 and 122 are disposed at the bottom edge of the active region (near the conductive path of the inductors 101 and 102).

In addition, the designer may, according to the practical need, choose to dispose the shielding layer between the inductor and the substrate to reduce the coupling effect. The shielding layer (not shown) can be disposed according to the standard design specification of a wafer manufacturer. The present embodiment may waive the step of forming the shielding layer so as to avoid generation of parasite capacitors.

The oscillation frequency of the VCO 100 is determined by the inductor value of the inductors 101 and 102 and the capacitance value of the capacitors 111˜114. In the embodiment, a designer can first decide the layout of the inductors 101 and 102 (that is, decide the inductor value), then decide the capacitance value of capacitors 111˜114 according to the determined inductor value and the targeted frequency (that is, decide the area of capacitors 111˜114). Thus, the circuit design can be more flexible in accordance with the present embodiment.

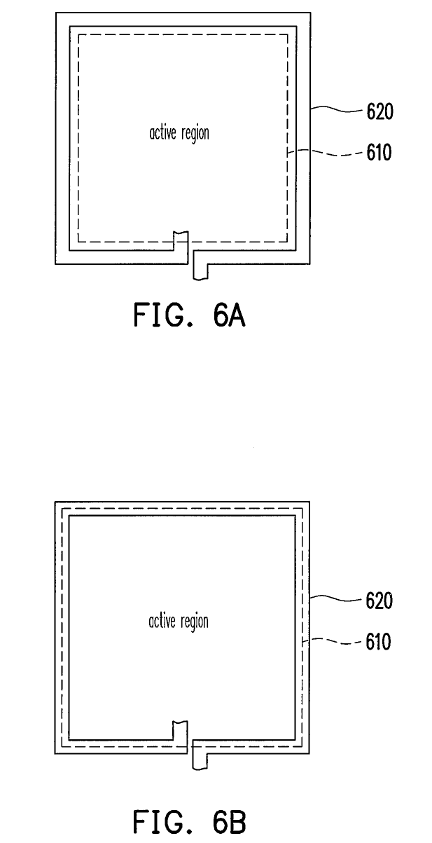

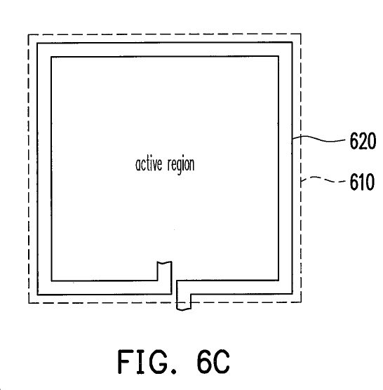

Though the conductive path of the inductors 101 and 102 of the aforementioned embodiment is disposed near the left or right edge of the active region along the direction of the active region edge, this arrangement is only one of the examples of the present invention. The inductor layout of the present invention should not be limited by this. The conductive path of the inductors can be disposed surrounding the edge of the active region to form a single turn wire. FIG. 6A illustrates the inductor layout according to another embodiment of the present invention. The inductor 620 in FIG. 6A circles the active region 610 to form a single turn wire. The conductive path of the inductor 620 is disposed near the edge of the active region 610 along the direction of the edge of the active region 610.

The designer can decide whether the conductive path of the inductor 620 is disposed near the edge of the active region 610, or decide whether a part (or the whole) of the conductive path of the inductor 620 is overlapped in the inner edge of the active region 610. FIG. 6B illustrates the inductor layout according to another embodiment of the present invention. In FIG. 6B, the conductive path of the inductor 620 is disposed near the edge of the active region 610 along the direction of the edge of the active region 610. The difference between FIG. 6A and FIG. 6B is that a part of the conductive path of the inductor 620 is overlapped in the inner edge of the active region 610. FIG. 6C illustrates the inductor layout according to another embodiment of the present invention. In FIG. 6C, the conductive path of the inductor 620 is disposed near the edge of the active region 610 along the direction of the edge of the active region 610. The difference between FIG. 6A and FIG. 6B is that the whole conductive path of the inductor 620 is overlapped in the inner edge of the active region 610.

The abovementioned conductive path of the inductor can be disposed in a single conductive layer, for example, the whole conductive path of a single turn wire inductor is disposed in a top metal layer. The designer can also dispose the conductive path of the inductor within several conductive layers to meet the requirement.

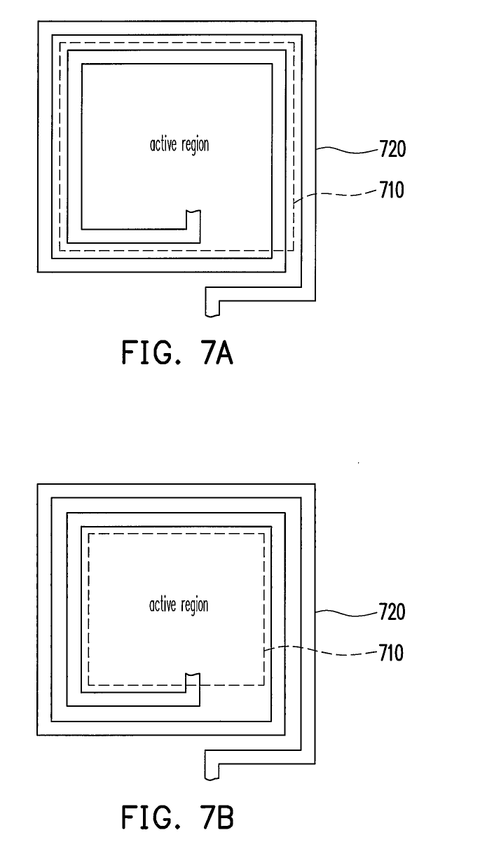

The conductive path of the inductors can be disposed surrounding the edge of the active region to form a multi-turn wire. FIG. 7A illustrates the inductor layout according to another embodiment of the present invention. A part of the conductive path of the inductor 720 in FIG. 7B is overlapped in the inner edge of the active region 710.

In practice, the designer can also dispose the whole conductive path of the inductor 720 outside of the active region 710. FIG. 7B illustrates the inductor layout according to another embodiment of the present invention. In FIG. 7B, the conductive path of the inductor 720 is disposed near the edge of the active region 710 along the direction of the edge of the active region 710. The difference between FIG. 7A and FIG. 7B is that the whole conductive path of the inductor 720 is disposed outside of the active region 710.

The abovementioned multi-turn conductive path of the inductor can be disposed in a single conductive layer, for example, the whole conductive path of the inductor is disposed in a top metal layer. Alternatively, the designer can dispose the conductive path of the inductor within a plurality of conductive layers to meet the requirement.

According to the spirit of the present invention, an embodiment of the manufacturing method of an inductor is provided. The manufacturing method of the inductor includes: forming at least an active region on a substrate, wherein the active region includes at least a circuit; forming a shielding layer over the substrate; and forming a conductive path over the substrate, and the conductive path is arranged along the direction of the edge of the active region and is disposed near the edge of the active region. Wherein, two ends of the conductive path are the two ends of the inductor, and the shielding layer is disposed between the inductor and the substrate. The conductive path circles the active region to form a single turn wire, or circles the active region to form a multi-turn wire. The conductive path can be disposed in a single conductive layer (located over the substrate), or within plural conductive layers. The conductive layer can be a top metal layer, or other metal layer or polysilicon layer and the like. The shielding layer can be disposed according to the standard design specification of a wafer manufacturer. The shielding layer disposed between the inductor and the substrate is used to reduce the coupling effect, and a designer can selectively waive the step of forming the shielding layer according to the practical need.

In summary, according to the present invention, the conductive path of the inductor is disposed near the edge of the active region and extends toward the edge of the active region; therefore, under any inductor layout standard process, the area taken up by the inductor can be reduced without increasing the manufacturing cost and production complexity.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An inductor layout, comprising:
a substrate, comprising at least an active region, wherein the active region comprises at least a circuit; and
a conductive path, disposed near an edge of the active region over the substrate and arranged along a direction of the edge of the active region, wherein two ends of the conductive path are two ends of the inductor.

2. The inductor layout as claimed in claim 1, wherein the conductive path circles the active region to form a single turn wire.

3. The inductor layout as claimed in claim 1, wherein the conductive path circles the active region to form a multi-turn wire.

4. The inductor layout as claimed in claim 1, wherein the conductive path is disposed in a conductive layer, and the conductive layer is above the substrate.

5. The inductor layout as claimed in claim 4, wherein the conductive layer is a top metal layer.

6. The inductor layout as claimed in claim 1, wherein the conductive path is disposed within a plurality of conductive layers, and the conductive layers are above the substrate.

7. The inductor layout as claimed in claim 1, further comprising a shielding layer, wherein the shielding layer is disposed between the inductor and the substrate.

8. A fabricating method of an inductor, comprising:
forming at least an active region on the substrate, wherein the active region comprises at least a circuit. forming a conductive path over the substrate, and the conductive path is disposed near the edge of the active region and is arranged along a direction of an edge of the active region, wherein two ends of the conductive path are two ends of the inductor.

9. The fabricating method of an inductor as claimed in claim 8, wherein the conductive path circles the active region to form a single turn wire.

10. The fabricating method of an inductor as claimed in claim 8, wherein the conductive path circles the active region to form a multi-turn wire.

11. The fabricating method of an inductor as claimed in claim 8, wherein the conductive path is disposed in a conductive layer, and the conductive layer is above the substrate.

12. The fabricating method of an inductor as claimed in claim 11, wherein the conductive layer is a top metal layer.

13. The fabricating method of an inductor as claimed in claim 8, wherein the conductive path is disposed within a plurality of conductive layers, and the conductive layers are above the substrate.

14. The fabricating method of an inductor as claimed in claim 8, further comprising: forming a shielding layer, wherein the shielding layer is disposed between the inductor and the substrate.
